(19) United States
(12) Patent Application Publication
(10) Pub. No.: US 2025/0374589 A1
(43) Pub. Date: Dec. 4, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Huei-Tang Wang, Hsinchu (TW); Yuan-Tsung Tsai, Hsinchu (TW); Jhu-Min Song, Hsinchu (TW); Chi-Te Lin, Hsinchu (TW); Jiou-Kang Lee, Hsinchu (TW); Tsung-Yin Hsu, Hsinchu (TW); Ying-Ming Wang, Hsinchu (TW); Shih-Hao Chen, Hsinchu (TW)

(73) Assignee: Taiwan Semiconductor Manufacturing Company, Ltd., Hsinchu (TW)

(21) Appl. No.: 18/678,783

(22) Filed: May 30, 2024

(51) Int. Cl. H01L 29/78; H01L 21/265; H01L 21/266; H01L 29/66

(52) U.S. Cl. CPC H10D 30/603; H01L 21/26513; H01L 21/266; H10D 30/022; H10D 30/0281; H10D 30/65

(57) ABSTRACT

A semiconductor device including an active region, a gate dielectric layer, a gate electrode, and a source/drain region is provided. The active region is formed in a substrate. The gate dielectric layer is located on the active region and has an extension area on opposite sides of the gate dielectric layer respectively. The gate electrode is located on the gate dielectric layer and exposes the two extension areas. The source/drain region is located in the active region on one side of the gate dielectric layer.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of gate induced drain leakage (GIDL) in a semiconductor device.

FIGS. 2A and 2B are cross-sectional views of a semiconductor device along planes defined by the X direction and the Z direction according to an embodiment of the present disclosure.

FIGS. 3A to 3E are schematic diagrams of various stages of a patterning process according to an embodiment of the present disclosure.

FIG. 4 is a schematic diagram showing a distance between an edge of the gate dielectric layer and an edge of the gate electrode according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Metal-Oxide-Semiconductor Field Effect Transistor (MOSFET) is a semiconductor component widely used in analog circuits and digital circuits. It mainly utilizes the bias voltage of the gate (G) to attract carriers at the interface between the semiconductor and the oxide layer of the MOS capacitor to form a current channel between the source (S) and the drain (D). The current channel is controlled by controlling the bias voltage of the gate (G) on and off.

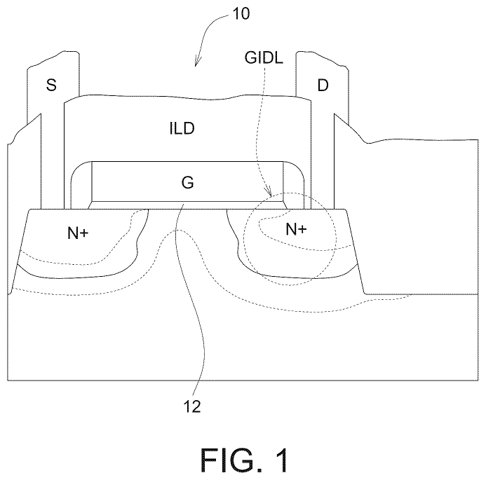

With the advancement of semiconductor technology, the characteristic size of the MOSFET 10 continues to shrink to increase the integration of integrated circuits, but this makes short channel effects (SCEs) more and more significant. For example, in FIG. 1, gate induced drain leakage (GIDL) and hot carrier injection (HCl) would seriously affect the performance and reliability of the MOSFET 10.

Research shows that by comparing the hot carrier reliability of high-voltage drain extending MOS (DEMOS) transistors and traditional low-voltage MOS transistors, it can be confirmed that under high drain bias test conditions, the greater the bias voltage of the gate (G), the larger the maximum impact ionization region in the drift region will be closer to the drain (D) due to the Kirk effect, and at the same time, the electric field generated in the channel region becomes stronger. Since the defects generated by hot carriers are closer to the drain (D), the control ability of the gate (G) becomes weaker, resulting in greater on-resistance degradation. The defects caused by the strong electric field in the channel region cause the degradation of on-resistance to increase as the bias voltage of gate (G) increases. As shown in FIG. 1, the experimental results can confirm that the injection of hot electrons in the accumulation area close to the channel region and the injection of hot holes in the accumulation area close to the gate spacers are the main causes of the abnormal degradation of the on-resistance. The injection of hot holes creates positively charged traps in the gate dielectric layer 12, which cause negatively charged mirror electrons to be induced in the accumulation area, thereby reducing the on-resistance.

To avoid punch through and short channel effect due to the relatively light doping of the p-region under the gate electrode, the gate length of DEMOS transistor needs to be fairly long. Compared to DEMOS, the lateral diffused MOS (LDMOS) transistors need an additional mask and implant step to increase channel doping and form a laterally diffused body region from source side beneath the gate electrode. In general, DEMOS transistor is suitable for high-voltage, low-current applications, such as display drivers. The LDMOS transistor is suitable for high-voltage and high-current applications, such as class-D amplifier, power management IC, and motor drivers.

Take 0.5 μm 40V N-type DEMOS transistor as an example, this semiconductor device needs a lower dosage n-type drift region as a drain extension for 40V drain operation. A light doped high voltage P-well is implemented in the beginning of process flow for this purpose. The high voltage gate oxide was introduced for 40V operation and inserted between the n-type drift region and the gate electrode.

Compared to the conventional CMOS transistor, this DEMOS transistor has a gate dielectric layer with an extending area out of the sidewalls of the gate electrode, the gate dielectric layer can be used to reduce the gradient implant and further reduce the GIDL effect in the drain extension region close to the channel region.

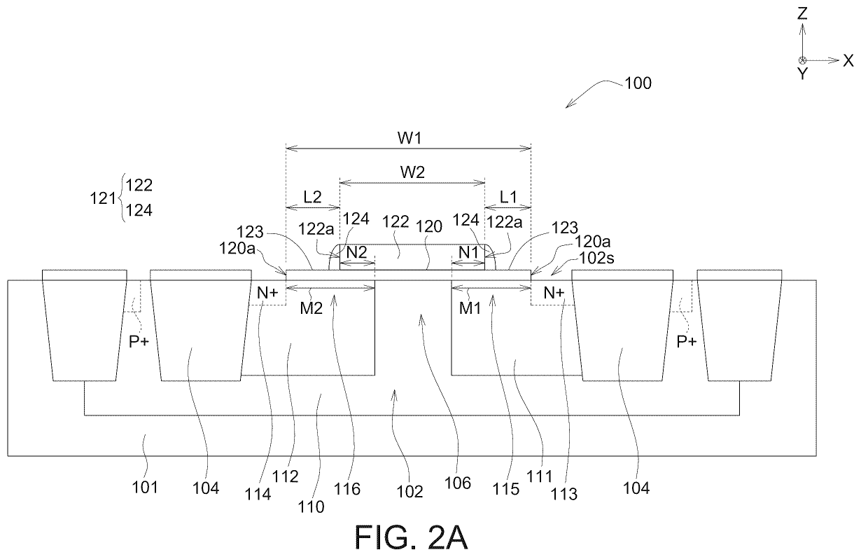

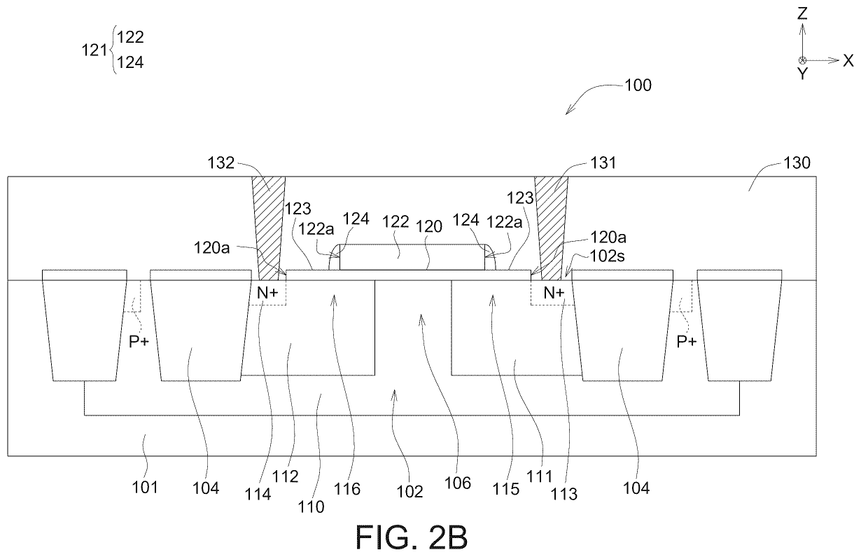

FIGS. 2A and 2B are cross-sectional views of the semiconductor device 100 along the plane defined by the X direction and the Z direction according to an embodiment of the present disclosure. The manufacturing method of the semiconductor device 100 is as follows. First, a substrate 101 is provided, such as a silicon substrate, an epitaxial silicon substrate, a silicon germanium semiconductor substrate, a silicon carbide substrate or a silicon-on-insulator (SOI) substrate, but it is not limited thereto. The substrate 101 may include a well region 110 doped with dopants of a conductivity type, such as a P conductivity type.

Next, another patterning process (such as a photolithography and etching process) can be performed on the substrate 101 to form a trench (not shown) in the substrate 101 and define the active region 102 in the substrate 101, and then a deposition process is performed, such as a chemical vapor deposition (CVD) process, to fill the trench with dielectric material, and then a planarization process (such as chemical mechanical polishing process) is performed to remove the dielectric material outside the trench, thereby obtaining a shallow trench isolation (STI) structure 104 surrounding the active region 102. The depth of the shallow trench isolation structure 104 (e.g., the depth from the surface 102s of the active region 102) may be between 2500 angstroms and 3500 angstroms, but it is not limited thereto.

Next, an ion implantation process can be performed to implant appropriate dopants into a predetermined area of the active region 102 to form two drift regions 111 and 112 in the active region 102. The well region 110 can cover the entire range of the active region 102, and the two drift regions 111 and 112 are located in the active region 102 on both sides of the channel region 106, and the depth of the two drift regions 111 and 112 (from the surface 102s of the active region 102) may be between 2500 angstroms and 3500 angstroms, but it is not limited thereto. The well region 110 and the two drift regions 111 and 112 have opposite conductivity types. For example, in some embodiments, the well region 110 is a P-type well region and the two drift regions 111 and 112 are N-type lightly doped regions. In other embodiments, the well region 110 is an N-type well region, and the two drift regions 111 and 112 are P-type lightly doped regions. The dopants can be any suitable P-type or N-type dopants, implanted at any energy, and suitable for forming the well region 110 or the two drift regions 111, 112 of any concentration. For example, in one embodiment, boron ions (B+) are implanted at a relatively high energy between about 300 keV and about 650 keV and have a concentration or dose between about 0.5E13/cm² and about 5E13/cm² to form a P-type well region 110. In addition, arsenic ions or phosphorus ions are implanted at a relatively high energy between about 300 keV and about 650 keV and have a concentration or dose between about 1E13/cm² and about 5E13/cm² to form the two drift regions 111 and 112.

Next, a dielectric material is formed on the substrate 101, and a patterning process (such as a photolithography and etching process) is performed on the dielectric material to form a gate dielectric layer 120 on the substrate 101. The gate dielectric layer 120 has a width W1 in the X direction and a width in the Y direction (not shown). According to an embodiment of the present disclosure, the thickness of the gate dielectric layer 120 may range from 3 nm to 50 nm, but it is not limited thereto.

Next, a heavily doped N+ source region 114 and a heavily doped N+ drain region 113 are formed, which are separated by a channel region 106 located under the gate dielectric layer 120. Compared to the dopant concentration in the well region 110 and the two drift regions 111 and 112, heavily doped means a concentration of suitable impurities or dopants, such as arsenic ions or phosphorus ions, from about 1E15/cm² to about 5E15/cm².

In addition, the semiconductor device 100 further includes a drain extension region 115 between the channel region 106 and the drain region 113 and a source extension region 116 between the channel region 106 and the source region 114. The drain region 113 is electrically connected to the channel region 106 via the drain extension region 115, and the source region 114 is electrically connected to the channel region 106 via the source extension region 116. The distance or length L1 between an edge of the channel region 106 (which refers to as a starting point of the channel region 106) and an edge of the drain region 113 is referred to as the length of the drain extension region 115, and the distance or length L2 between the other edge of the channel region 106 (which refers to as an end point of the channel region 106) and an edge of the source region 114 is referred to as the length of the source extension region 116. Suitable distances or lengths of the drain extension region 115 and the source extension region 116 include from about 40 nm to about 100 nm, from about 30 nm to about 60 nm, or from about 20 nm to about 40 nm.

During reverse bias period, the depletion regions formed in the channel region 106 extend far enough to reduce the electric field per unit length and reach a high junction breakdown voltage (BV) toward the substrate 101. Therefore, the lightly doped drain extension region 115 becomes depleted during reverse bias and reduces most of the voltage applied to the drain region 113 of the high voltage DEMOS transistor, thereby achieving a high junction breakdown voltage (BV). In one embodiment, with the lightly doped drain extension region 115, an applied drain voltage of approximately 9 to 10 Volts will drop by approximately 6 Volts across the drain extension region 115, thereby limiting the voltage across the gate dielectric layer 120 approximately 3.6V, and a standard low I/O voltage gate dielectric layer 120 can be used as an isolation layer between channel region 106 and gate electrode 122.

Next, a gate structure is formed above the gate dielectric layer 120. The gate structure includes a polycrystalline silicon (polysilicon) or metal made gate electrode 122 and a gate spacer 124. The polysilicon or metal made gate electrode 122 and the channel region 106 are separated by a gate dielectric layer 120 and are not in direct contact. The width W2 of the polysilicon or metal made gate electrode 122 in the X direction is smaller than the width W1 of the gate dielectric layer 120 in the X direction, so that the edges (i.e., extension areas) of the gate dielectric layer 120 will be exposed from both sides of the gate structure. The distance extending outward from both sides of the gate electrode 122 (indicated by L1, L2) may be based on the size of the overlapping area (indicated by M1) of the gate dielectric layer 120 and the drain extension region 115 in the Z direction and the size of the overlapping area (indicated by M2) of the gate dielectric layer 120 and the source extension region 116.

In one embodiment, the drain extension region 115 and the source extension region 116 are located below the gate electrode 122, and the overlapping area (indicated by N1) of the gate electrode 122 and the drain extension region 115 can be smaller than the overlapping area (indicated by M1) of the dielectric layer 120 and the drain extension region 115, so that the overlapping area between the drain extension region 115 and the gate electrode 122 is reduced in exchange for an increase in breakdown voltage, so as to prevent reduction of on-current in the semiconductor device 100 with a short channel length. Suitable distances or lengths of the overlapping area include from about 50 nm to about 100 nm, from about 40 nm to about 80 nm, or from about 30 nm to about 60 nm. In the same manner, the overlapping area (indicated by N2) of the gate electrode 122 and the source extension region 116 may be smaller than the overlapping area (indicated by M2) of the gate dielectric layer 120 and the source extension region 116. Suitable distances or lengths of the overlapping area include from about 50 nm to about 100 nm, from about 40 nm to about 80 nm, or from about 30 nm to about 60 nm.

Affected by the reduction in the overlapping area of the gate electrode 122 and the drain extension region 115, the edges or corners on opposite sides of the gate dielectric layer 120 will extend out of the gate electrode 122 respectively. The distances or lengths between an edge of the gate dielectric layer 120 and an edge of the metal gate electrode 122 are called the lengths of the extension areas 123 (indicated by L1, L2). The extension distance or length L1 on the drain side is approximately equal to the length (indicated by M1) of the overlapping area of the gate dielectric layer 120 and the drain extension region 115 minus the length (indicated by N1) of the overlapping area of the gate electrode 122 and the drain extension region 115. In the same manner, a suitable extension distance or length L2 on the source side is approximately equal to the length (indicated by M2) of the overlapping area of the gate dielectric layer 120 and the source extension region 116 minus the length (indicated by N2) of the overlapping area of the gate electrode 122 and the source extension region 116.

The gate dielectric layer 120 may include one or more layers of dielectric materials, such as silicon oxide, silicon nitride, high-k dielectric materials, other suitable dielectric materials, and/or combinations thereof. Examples of high-k dielectric materials include HfO₂, HfSiO, HfSiON, HfTaO, HfTiO, HfZrO, zirconium oxide, alumina, titanium oxide, hafnium dioxide-aluminum oxide (HfO₂—Al₂O₃) alloy, other suitable high-k dielectric constant materials and/or combinations thereof. The gate dielectric layer 120 may be formed by CVD, ALD, or any suitable deposition technique.

The gate electrode 122 may include one or more layers of conductive materials, such as polycrystalline silicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials and/or any combination thereof. Gate electrode 122 may be formed by CVD, ALD, electroplating or other suitable deposition techniques. In addition, the gate spacer 124 covers the sidewall of the gate electrode 122. The material of the gate spacer 124 can be a dielectric material, such as silicon nitride, silicon oxynitride, silicon carbide, silicon oxide or a combination thereof.

According to an embodiment of the present disclosure, when the semiconductor device 100 is an N-conductivity type transistor, the gate electrode 122 can be made of a metal material with a work function of 3.9 eV to 4.3 eV, such as titanium aluminide (TiAl).), zirconium aluminide (ZrAl), tungsten aluminide (WAl), tantalum aluminide (TaAl), hafnium aluminide (HfAl) or titanium aluminum carbide (TiAlC) etc., but it is not limited thereto. When the semiconductor device 100 is a P-conductivity type transistor, the gate electrode 122 can be made of a metal material with a work function of 4.8 eV to 5.2 eV, such as titanium nitride (TiN), tantalum nitride (TaN) or tantalum carbide (TaC) etc., but it is not limited thereto. According to an embodiment of the present disclosure, a linear high-k dielectric layer can be disposed between the bottom surface of the gate electrode 122 and the gate dielectric layer 120, so the gate electrode 122 does not directly contact the gate dielectric layer 120. In yet another embodiment, the gate electrode 122 may directly contact the gate dielectric layer 120 without a high-k dielectric layer disposed therebetween.

Next, referring to FIG. 2B, at least one interlayer dielectric layer (ILD) 130 is formed and at least one conductive plug 131 is formed in the interlayer dielectric layer 130. The interlayer dielectric layer 130 covers the active region 102. The interlayer dielectric layer 130 may include amorphous SiOx, SiOxCyHz, SiOxCy, SiCx or related low-k value materials. The k value may range from 2.0 to 3.0 or 2.5 to 3.5. The interlayer dielectric layer 130 may be made of SiOx, SiOxCyHz, SiOxCy, SiCx or related low-k materials with ordered pores or non-pores. The term “ordered pores” as used herein refers to a defined arrangement of air-filled pores or air gaps formed within a dielectric material. The interlayer dielectric layer 130 with ordered pores has the characteristics of low dielectric constant and high mechanical strength. In some embodiments, the interlayer dielectric layer 130 may be formed by chemical vapor deposition (CVD), physical vapor deposition (PVD), atomic layer deposition (ALD), spin coating, or other suitable processes at a temperature between 450 degrees Celsius and 300 degrees Celsius. In some embodiments, the interlayer dielectric layer 130 may be produced by an additional annealing or ultraviolet (UV) curing process, but it may not be used.

In one embodiment, a conductive contact layer may be disposed on the source/drain regions 113, 114, and a conductive plug 131 passing through the interlayer dielectric layer 130 may be disposed above the conductive contact layer and electrically connected to the source/drain regions 113 and 114. The conductive contact layer includes a silicide layer, such as WSi, NiSi, TiSi or CoSi or other suitable silicide materials or alloys of metallic elements with silicon and/or germanium. The conductive plug 131 includes one or more layers of Co, Ni, W, Ti, Ta, Cu, Al, TiN, and TaN.

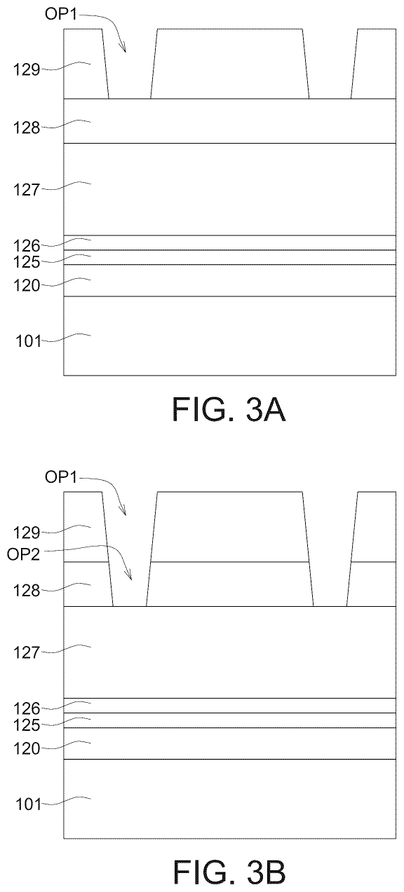

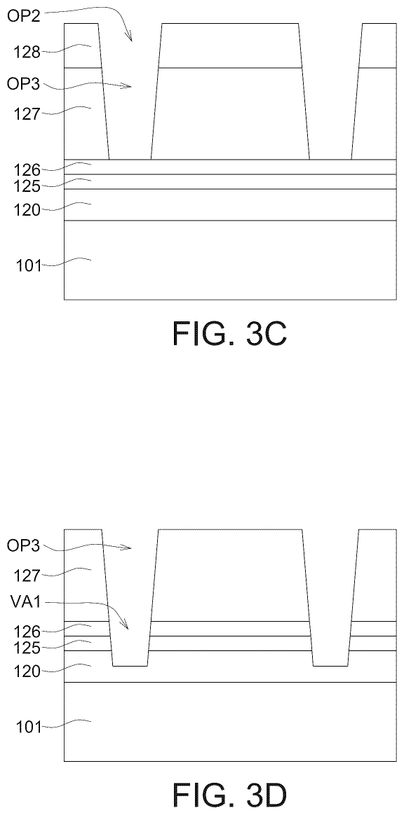

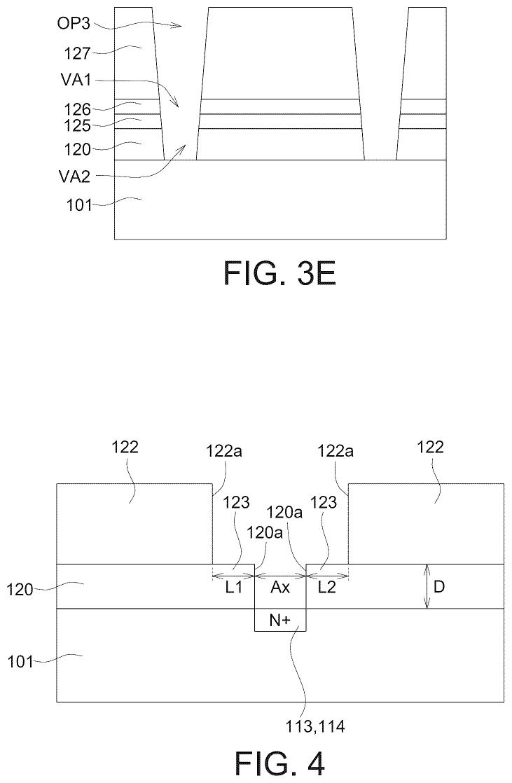

Referring to FIGS. 3A to 3E, schematic diagrams of various stages of the patterning process according to an embodiment of the present disclosure are illustrated. First, the uppermost first photoresist layer 129 is patterned to form a first opening OP1 in the first photoresist layer 129, and the first opening OP1 exposes the middle second photoresist layer 128. Next, the second photoresist layer 128 is patterned to form a second opening OP2 in the second photoresist layer 128, and the second opening OP2 exposes the lowermost third photoresist layer 127. Next, the third photoresist layer 127 is patterned to form a third opening OP3 in the third photoresist layer 127, and the third opening OP3 exposes the underlying liner layers 126 and 125. The above-mentioned patterned photoresist can have a pattern transferred thereon through an exposure and development process. The most commonly used patterned photoresist is a three-layer photoresist structure, but it is not limited thereto.

The third photoresist layer 127 is a bottom photoresist coated on the liner 126, which can prevent the liner 126 and/or the underlying layer from reflecting a significant amount of incident radiation during photoresist exposure and negatively affecting the quality of the pattern of the photoresist. The second photoresist layer 128 is an intermediate layer formed on the bottom photoresist. The second photoresist layer 128 is, for example, a silicon-containing resin polymer, which has a better etching selectivity, so that the line width uniformity (critical dimension uniformity) of after etching inspection (AEI) is better. The first photoresist layer 129 is, for example, a photosensitive layer, and can be exposed by using KrF/ArF light source (248 nm/193 nm) and EUV (13.5 nm) or charged particle beam (such as e-beam or Ion-beam). The exposure methods can use immersion or dry (non-immersion) lithography techniques.

Photo masks can be used during exposure, such as binary photo masks, phase shift masks (PSM), attenuated phase shifting masks (APSM), transmission type reticle or EUV reflective reticle to define exposed and unexposed areas. In another embodiment, a desired pattern may be written directly on the photoresists using a charged particle beam that does not require a photo mask.

Referring to the FIG. 3D, an etchant is used to etch the liners 126 and 125 exposed in the third opening OP3 to form a first patterned opening VAL. The first patterned opening VA1 exposes the gate dielectric layer 120. Next, referring to FIG. 3E, an etchant is used to etch the gate dielectric layer 120 exposed in the first patterned opening VA1 to form a second patterned opening VA2. The liners 126 and 125 may be composed of silicon oxide and/or silicon nitride materials (such as SiO₂, SiN, SiON, SiCN or SiOCN) and may be deposited through one or more processes, such as physical vapor deposition (PVD), chemical vapor deposition (CVD) or atomic layer deposition (ALD).

In one embodiment, the exposed portion of the gate dielectric layer 120 can be removed by using plasma dry etching and/or wet etching to expose the surface of the substrate 101. Wet etchants include, but are not limited to, mixed solutions of H₂O₂, CH₃COOH and HF.

Referring to FIG. 4, a schematic diagram in which an edge 120a of the gate dielectric layer 120 and an edge 122a of the metal gate electrode 122 are separated by a distance is illustrated. In one embodiment, an ion implantation is performed using the gate dielectric layer 120 as a mask to form a source/drain region 113 in the active region 102. Since the gate dielectric layer 120 has an extension area 123 on both sides respectively, and one of the extension areas 123 extends a length L1 from an edge 122a of the gate electrode 122, and another one of the extension areas 123 extends a length L2 from an edge 122a of another gate electrode 122, so that the ion implantation area Ax of the source/drain regions 113 and 114 between the two extension areas 123 can be reduced.

In addition, the gate electrode 122 made of polycrystalline silicon or metal is separated from the substrate 101 by the gate dielectric layer 120 without direct contact. The width of the gate electrode 122 made of crystalline silicon or metal in the X direction is smaller than the width of the gate dielectric layer 120 in the X direction, so that the edges 120a of the gate dielectric layer 120 extend out from both sides of the gate electrode 122. In some embodiments, the length of the extension area 123 is, for example, about 40±30 nm, 30±20 nm, or 10±5 nm, and the thickness D of the extension area 123 is, for example, about 230±200 nm or 130±100 nm. The lengths L1 and L2 of the extension areas 123 can control the ion implantation area Ax of the source/drain region 113, 114 to minimize the implant pattern, so as to increase the distance between the source/drain regions 113, 114 and the channel region 106, thereby reducing the electric field per unit length and reaching a high junction breakdown voltage (BV) towards the substrate 101. As a result, the gradient implant can be reduced and the GIDL effect can be further suppressed by using the extension area 123.

The present disclosure relates to a semiconductor device and a manufacturing method thereof, which are used to improve the gate-induced drain leakage (GIDL) in the semiconductor device. It can be found from the experimental results that the hot electron injection that occurs in the accumulation area close to the channel and the hot hole injection that occurs in the accumulation area close to the gate spacer are the main reasons for the abnormal degradation of the on-resistance. Therefore, in this disclosure, in order to avoid the leakage current due to short channel effect, a gate dielectric layer with an extending area out of the edges of the gate electrode is provided, the gate dielectric layer can be used to reduce the gradient implant and further reduce the GIDL effect in the drain extension region close to the channel region. In addition, the ion implantation area of the source/drain region located on one side of the gate dielectric layer can also be reduced.

According to some embodiments of the present disclosure, a semiconductor device including an active region, a gate dielectric layer, a gate electrode, and a source/drain region is provided. The active region is formed in a substrate. The gate dielectric layer is located on the active region and has an extension area on opposite sides of the gate dielectric layer respectively. The gate electrode is located on the gate dielectric layer and exposes the two extension areas. The source/drain region is located in the active region on one side of the gate dielectric layer.

According to some embodiments of the present disclosure, a semiconductor device including a drain extension region, a gate dielectric layer, a gate electrode and a drain region is provided. The drain extension region is formed in a substrate. The gate dielectric layer is located on the drain extension region. The gate dielectric layer has an extension area on one side, and the extension area overlaps the drain extension region. The gate electrode is located on the gate dielectric layer and exposes the extension area. The drain region is located in the substrate on one side of the gate dielectric layer.

According to some embodiments of the present disclosure, a method of manufacturing a semiconductor device including the following steps is provided. An active region is formed in a substrate. A gate dielectric layer is deposited on the active region and has an extension area on opposite sides of the gate dielectric layer respectively. The gate electrode is formed on the gate dielectric layer and exposes the two extension areas. An ion implantation is performed using the gate dielectric layer as a mask to form a source/drain region located in the active region on one side of the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an active region formed in a substrate;
a gate dielectric layer located on the active region and having an extension area on opposite sides of the gate dielectric layer respectively;
a gate electrode located on the gate dielectric layer and exposing the two extension areas; and
a source/drain region located in the active region on one side of the gate dielectric layer.

2. The semiconductor device of claim 1, wherein the active region comprises a channel region, a drain extension region and a source extension region, and the channel region is located between the drain extension region and the source extension region.

3. The semiconductor device of claim 2, wherein an overlapping area of the gate dielectric layer with the channel region, the drain extension region, and the source extension region is greater than an overlapping area of the gate electrode layer with the channel region, the drain extension region, and the source extension region.

4. The semiconductor device of claim 3, wherein a distance between an edge of the gate dielectric layer and an edge of the gate electrode is a length of each of the extension areas.

5. The semiconductor device of claim 4, wherein the length of each of the extension areas is a length of the overlapping area of the gate dielectric layer and the drain extension region minus a length of the overlapping area of the gate electrode and the drain extension region.

6. The semiconductor device of claim 4, wherein the edge of the gate dielectric layer is flush with an edge of the source/drain region.

7. The semiconductor device of claim 1, further comprising a gate spacer covering sidewalls of the gate electrode.

8. The semiconductor device of claim 1, further comprising at least one interlayer dielectric layer and at least one conductive plug formed in the interlayer dielectric layer, wherein the interlayer dielectric layer covers the active region, and the conductive plug is electrically connected to the source/drain region.

9. A semiconductor device, comprising:
a drain extension region formed in a substrate;
a gate dielectric layer located on the drain extension region, the gate dielectric layer has an extension area on one side, and the extension area overlaps the drain extension region;
a gate electrode located on the gate dielectric layer and exposing the extension area; and
a drain region located in the substrate on the side of the gate dielectric layer.

10. The semiconductor device of claim 9, wherein an overlapping area of the gate dielectric layer and the drain extension region is greater than an overlapping area of the gate electrode layer and the drain extension region.

11. The semiconductor device of claim 10, wherein a distance between an edge of the gate dielectric layer and an edge of the gate electrode is a length of the extension area.

12. The semiconductor device of claim 11, wherein the edge of the gate dielectric layer is flush with an edge of the drain region.

13. A method of manufacturing a semiconductor device, comprising:
forming an active region in a substrate;
depositing a gate dielectric layer on the active region, the gate dielectric layer having an extension area on opposite sides of the gate dielectric layer respectively;
forming a gate electrode on the gate dielectric layer and exposing the two extension areas from the gate electrode; and
performing an ion implantation by using the gate dielectric layer as a mask to form a source/drain region located in the active region on one side of the gate dielectric layer.

14. The method of claim 13, wherein the active region comprises a channel region, a drain extension region and a source extension region, and the channel region is located between the drain extension region and the source extension region.

15. The method of claim 14, wherein an overlapping area of the gate dielectric layer with the channel region, the drain extension region, and the source extension region is greater than an overlapping area of the gate electrode layer with the channel region, the drain extension region, and the source extension region.

16. The method of claim 15, wherein a distance between an edge of the gate dielectric layer and an edge of the gate electrode is a length of each of the extension areas.

17. The method of claim 16, wherein the length of each of the extension areas is a length of the overlapping area of the gate dielectric layer and the drain extension region minus a length of the overlapping area of the gate electrode and the drain extension region.

18. The method of claim 16, wherein the edge of the gate dielectric layer is flush with an edge of the source/drain region.

19. The method of claim 13, further comprising forming a gate spacer covering sidewalls of the gate electrode.

20. The method of claim 13, further comprising forming at least one interlayer dielectric layer and at least one conductive plug formed in the interlayer dielectric layer, wherein the interlayer dielectric layer covers the active region, the conductive plug is electrically connected to the source/drain region.
